(19) United States
(12) Patent Application Publication
(10) Pub. No.: US 2024/0164038 A1
(43) Pub. Date: May 16, 2024

(54) VEHICLE DISPLAY DEVICE WITH PROTECTIVE FILM TO CONTAIN GLASS FRAGMENTS

(71) Applicant: Atieva, Inc., Newark, CA (US)

(72) Inventor: Lucas Jungmann, Newark, CA (US)

(21) Appl. No.: 18/561,595

(22) PCT Filed: May 16, 2022
(86) PCT No.: PCT/US2022/072342

§ 371 Date: Nov. 16, 2023

Related U.S. Application Data
(60) Provisional application No. 63/201,870, filed on May 17, 2021.

(51) Int. Cl. H05K 5/03; B60K 35/22

(52) U.S. Cl. CPC H05K 5/03; B60K 35/22

(57) ABSTRACT

A vehicle display device comprises: a housing forming an opening to an interior; a display module positioned in the interior of the housing, the display module including a substrate; a cover glass that covers the opening to the interior of the housing, the cover glass at least partially bounded by an exposed glass edge, the cover glass attached to the substrate by an optically clear adhesive, wherein an outermost region of the cover glass extends beyond an edge of the substrate; and a protective film positioned along at least part of the exposed glass edge, the protective film attached to an inside of the cover glass at the outermost region.

### CROSS-REFERENCE TO RELATED APPLICATION

This application claims priority to U.S. Patent Application No. 63/201,870, filed on May 17, 2021, and entitled “VEHICLE DISPLAY DEVICE WITH PROTECTIVE FILM TO CONTAIN GLASS FRAGMENTS,” the disclosure of which is incorporated by reference herein in its entirety.

### TECHNICAL FIELD

This document relates to a vehicle display device with a protective film to contain glass fragments.

### BACKGROUND

Electronic displays in automobiles are typically placed in front of the occupant line of sight for ease of viewing and interaction. Electronic displays can be covered with a cover glass to protect the display from the elements, for example so the display can be touched by the occupant to interact with the display. Similar to many glass products the risk of glass failure and cracking can occur in a number of manners such as vehicle crash events or electronic display misuse.

Some existing electronic displays cover the edge of the cover glass with a frame or bezel of another material, such as plastic. However, such displays can be considered less aesthetically appealing because the clean appearance of the cover glass is interrupted by an edge of non-glass material.

### SUMMARY

In a first aspect, a vehicle display device comprises: a housing forming an opening to an interior; a display module positioned in the interior of the housing, the display module including a substrate; a cover glass that covers the opening to the interior of the housing, the cover glass at least partially bounded by an exposed glass edge, the cover glass attached to the substrate by an optically clear adhesive, wherein an outermost region of the cover glass extends beyond an edge of the substrate; and a protective film positioned along at least part of the exposed glass edge, the protective film attached to an inside of the cover glass at the outermost region.

Implementations can include any or all of the following features. The protective film extends around an entirety of the exposed glass edge. The exposed glass edge extends around an entire perimeter of the cover glass. The protective film is transparent. The protective film comprises a polymer resin. The protective film comprises a polyethylene terephthalate film. The substrate defines an active pixel area for the display module. The protective film is positioned entirely outside the active pixel area. The display module further includes a frame positioned adjacent at least one edge of the display module. The vehicle display device further comprises an adhesive applied between the protective film and the frame. The adhesive is included in a double-sided tape positioned between the protective film and the frame. The adhesive attaches the protective film and the frame to each other and is not applied elsewhere at the inside of the cover glass. The frame comprises a first frame and a second frame, wherein the adhesive is applied only between the protective film and the first frame, wherein the first frame is attached to the second frame, and wherein the second frame is attached to the display module. The frame is positioned adjacent an entire perimeter of the display module. The vehicle display device further comprises foam positioned between the outermost region and the edge of the housing. The display module further includes a frame positioned adjacent at least one edge of the substrate, the vehicle display device further comprising adhesive positioned between the foam and the frame. The foam abuts the protective film. The vehicle display device comprises an instrument cluster device for a vehicle.

In a second aspect, a vehicle display device comprises: a housing forming an opening to an interior; a display module positioned in the interior of the housing, the display module including a substrate; a cover glass that covers the opening to the interior of the housing, the cover glass at least partially bounded by an exposed glass edge, the cover glass attached to the substrate by an optically clear adhesive, wherein an outermost region of the cover glass extends beyond an edge of the substrate; and means for containing glass fragments of the cover glass, the means positioned along at least part of the exposed glass edge, the means attached to an inside of the cover glass at the outermost region.

Implementations can include the following feature. The means extends around an entirety of the exposed glass edge, wherein the means is transparent, and wherein the means comprises a polyethylene terephthalate film.

### BRIEF DESCRIPTION OF DRAWINGS

FIG. 1 shows a perspective view of a front of an example of a display device for a vehicle.

FIG. 2 shows a perspective view of a rear of the display device of FIG. 1.

FIG. 3 shows an example of a portion of the housing and cover glass of the display device of FIG. 1.

FIG. 4 shows an example of a cross section of the cover glass and an interior of the display device of FIG. 1.

FIG. 5 shows another example of a cross section of the cover glass and interior of the display device of FIG. 1.

FIG. 6 shows another example of a cross section of the cover glass and interior of the display device of FIG. 1.

FIG. 7 shows another example of a cross section of the cover glass and interior of the display device of FIG. 1.

FIG. 8 shows a perspective view of an example of the cover glass of FIG. 1 with a protective film.

Like reference symbols in the various drawings indicate like elements.

### DETAILED DESCRIPTION

This document describes examples of systems and techniques for providing a vehicle display device with a protective film to contain glass fragments. Some implementations use an adhesive-backed, polymer-based transparent film affixed to a back side of the display cover glass to contain glass shards in the event of a cover glass fracture or failure. If a cover glass fracture event occurs, broken glass elements can remain affixed to the cover glass film and the display module. The protective film can be applied to an entire perimeter of the cover glass, or to one or more portions of the perimeter of a cover glass. Some polymer film materials can have relatively large elongation properties, which provide a place for the energy of fracture to be dissipated into. The film can be optically clear so as to have at most a negligible effect on the electronic display's optical performance. A relatively thin film can be integrated within the existing display structure stack. For example, this can avoid having to increase the display border size or display module thickness. A polymer-based film can be placed on the back of the cover glass, because such films are softer than glass and may decrease the perceived visual or tactile quality if placed on the front side. The film can be placed outside of the active pixel area of the electronic display so that is does not affect the optical performance. A film on the back of the cover glass is integral to the display module, for example such that the structural frame and other components of the display module can rely on the protective film for support onto the cover glass. A protective film can act as a structural bridge between the display module and the cover glass.

Examples herein refer to a protective film. As used herein, a protective film includes one or more materials allowing the protective film to be shaped into a relatively thin layer and be affixed to a planar or curved glass panel. The protective film can include a polymer resin. The polymer resin can include a thermoplastic polymer, including, but not limited to, a thermoplastic elastomer. For example, the protective film can include polyethylene terephthalate.

Examples herein refer to a substrate being transparent. As used herein, being transparent is used substantially synonymously with being optically clear. As used herein, a substrate (such as a protective film or a cover glass) is transparent if it has a transmittance within at least part of the visible-light spectrum of at least about 80%. In some implementations, a substrate can be considered transparent if it has a transmittance within most of the visible-light spectrum of at least about 80%.

Examples herein refer to a display device having a cover glass. As used herein, a cover glass is a transparent substrate. A transparent substrate can be made of, but is not limited to, a glass material. For example, a cover glass can be made from chemically strengthened glass. A cover glass can be planar or non-planar. For example, a cover glass can have a curved shape. A cover glass can be compatible with use of touchscreen technology for allowing a user to make inputs using the cover glass, wherein content is visually presented at the cover glass. In some implementations, the cover glass can facilitate use of capacitive and/or resistive touch sensing, to name just two examples.

Examples herein refer to an adhesive used with one or more components of a vehicle display device. As used herein, an adhesive is compatible with the environmental conditions that can occur within vehicles in different situations around the world. In some implementations, the adhesive can be capable of withstanding the environmental testing conditions that may apply to vehicles in one or more geographic regions. Such conditions can relate to durability or performance under different aspects such as temperature ranges, humidity ranges, or exposure to sunlight, to name just a few examples.

Examples herein refer to a vehicle. A vehicle is a machine that transports passengers or cargo, or both. A vehicle can have one or more motors using at least one type of fuel or other energy source (e.g., electricity). Examples of vehicles include, but are not limited to, cars, trucks, and buses. The number of wheels can differ between types of vehicles, and one or more (e.g., all) of the wheels can be used for propulsion of the vehicle. The vehicle can include a passenger compartment accommodating one or more persons. At least one vehicle occupant can be considered the driver; various tools, implements, or other devices, can then be provided to the driver. In examples herein, any person carried by a vehicle can be referred to as a “driver” or a “passenger” of the vehicle, regardless whether the person is driving the vehicle, or whether the person has access to controls for driving the vehicle, or whether the person lacks controls for driving the vehicle.

Examples herein refer to a front, rear, top or a bottom. These and similar expressions identify things or aspects in a relative way based on an express or arbitrary notion of perspective. That is, these terms are illustrative only, used for purposes of explanation, and do not necessarily indicate the only possible position, direction, and so on.

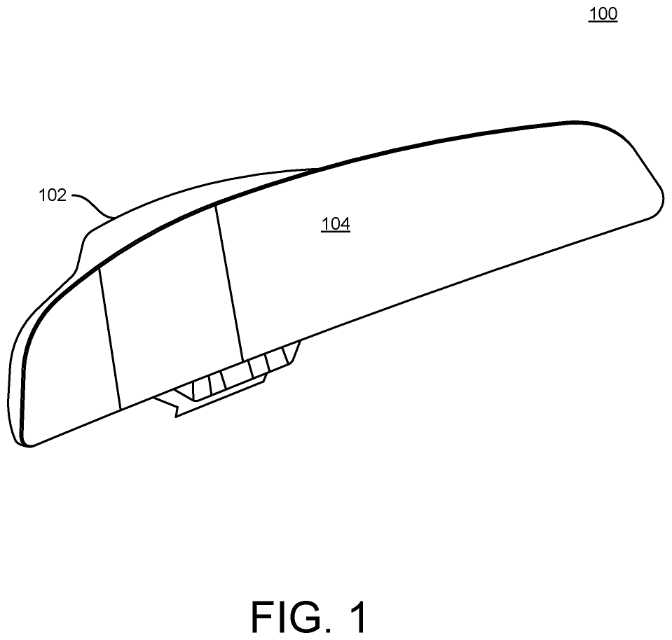

FIG. 1 shows a perspective view of a front of an example of a display device 100 for a vehicle. The display device 100 or any component thereof can be used with one or more other examples described elsewhere herein. In some implementations, the display device 100 can be part of a dashboard of a vehicle. For example, the display device 100 can provide a user interface to an occupant of the vehicle, such as in form of an instrument cluster.

The display device 100 includes a housing 102 and a cover glass 104. The housing 102 can form an opening (not visible) into an interior space. The interior space can accommodate components such as a display module. The housing 102 can be configured for mounting the display device 100 to structure in the vehicle. For example, the housing 102 can provide that the display device 100 is positioned in front of and/or above the dashboard so as to be easy to see and reach.

The cover glass 104 is positioned at the opening into the interior of the housing 102. The cover glass 104 can provide a view of content presented by a display module within the housing 102. In some implementations, the cover glass 104 facilitates one or more types of user input by way of touchscreen technology.

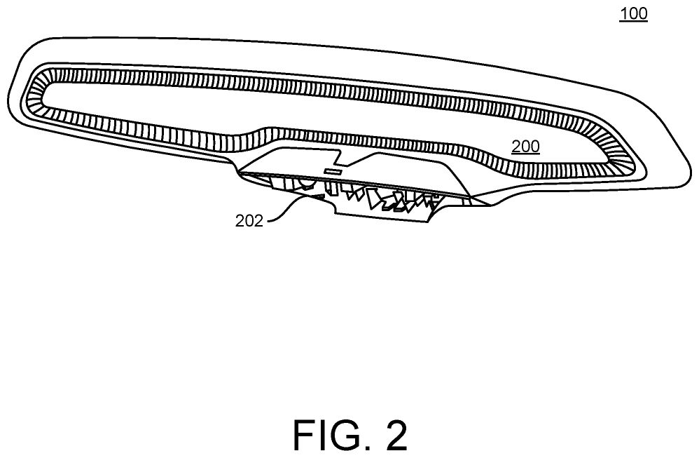

FIG. 2 shows a perspective view of a rear of the display device 100 of FIG. 1. The housing 102 can include a removable cover 200 that can allow access to a display module or other components of the display device 100. The removable cover 200 can be made of any suitable material, including, but not limited to, by plastic or metal. The housing 102 can include a connection portion 202. For example, the connection portion 202 can facilitate mounting of the display device 100 onto some structure (e.g., a dashboard), and communication between other components elsewhere in the vehicle and the display module and/or a touchscreen component.

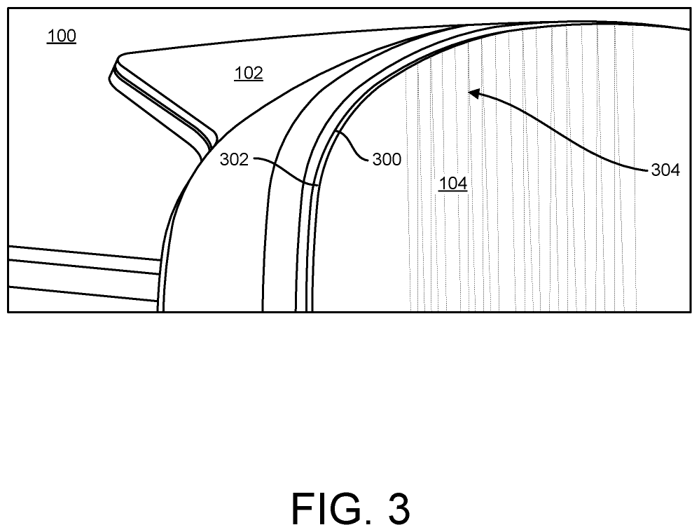

FIG. 3 shows an example of a portion of the housing 102 and cover glass 104 of the display device 100 of FIG. 1. The housing 102 has an edge 300 around the opening to the interior. The cover glass 104 has an edge 302. However, the edge 300 of the housing does not cover the edge 302 of the cover glass 104. Rather, the cover glass 104 here is a free-floating cover glass that does not have a bezel or frame, such that the edge 302 is not encapsulated but is an exposed glass edge. For example, the edge 302 can have a rounded profile. In some implementations, the edge 302 is an exposed glass edge around an entire perimeter of the cover glass 104. In some implementations, a portion of the perimeter of the cover glass 104 can be bounded by a frame or bezel, and the edge 302 can then be an exposed glass edge throughout the remaining perimeter of the cover glass 104.

In its more central portions, the cover glass 104 can be attached to some structure inside the display device 100. However, such structure does not necessarily extend to the periphery of the cover glass 104. Rather, an outermost region 304 of the cover glass 104 can extend beyond the structure to which the center of the cover glass 104 is attached. If the outermost region 304 of the cover glass 104 were not secured, it is possible that the glass in this area could fragment if the vehicle is involved in a crash or if the display device 100 is otherwise subjected to force or impact. Such possibility can be eliminated or reduced by use of one or more protective films, for example as described below.

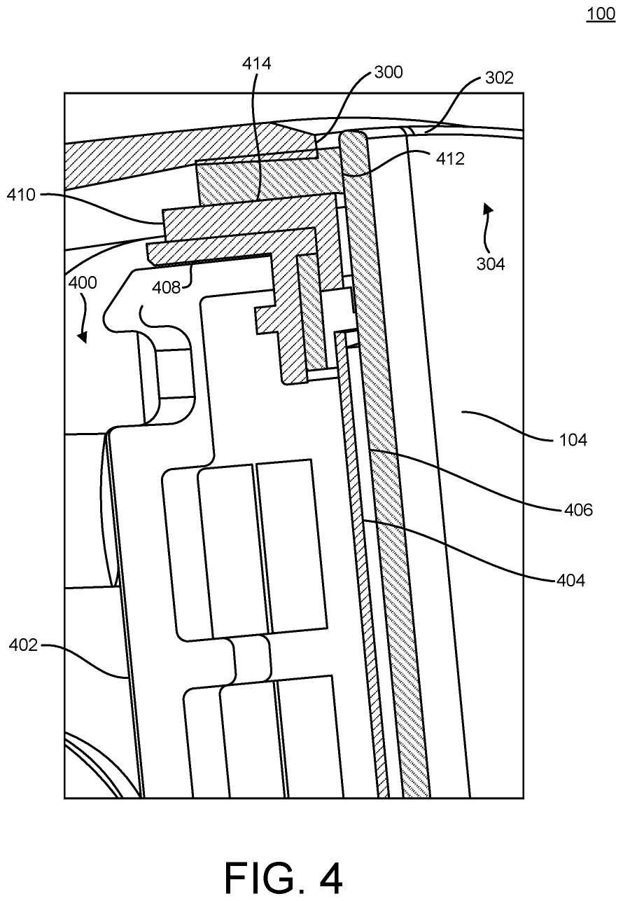

FIG. 4 shows an example of a cross section of the cover glass 104 and an interior 400 of the display device 100 of FIG. 1. The interior 400 formed by the housing 102 has an opening that is defined by the edge 300.

Within the interior 400, the display device 100 includes a display module 402 which is here only partially visible (e.g., one or more components may have been omitted for simplicity). The display module 402 can use one or more technologies for presenting content. In some implementations, the display module uses a thin-film transistor display device. A liquid crystal display (LCD) device or an organic LCD can be illuminated using light-emitting diodes, to name just a few examples. The display module 402 can include touchscreen technology to facilitate user input from touching of, or gestures performed at, the cover glass 104.

The display module 402 includes a substrate 404 that is used for presenting content and/or detecting input. One or more central portions of the cover glass 104 can be attached to the substrate 404 by way of a layer 406. The layer 406 can include an adhesive. For example, an optically clear adhesive can be applied as the layer 406. In some implementations, the display module 402 can have an active pixel area defined by the substrate 404 or otherwise. The active pixel area corresponds to the area where respective picture elements of the display module 402 can be individually addressed to form the visual content to be presented.

The display device 100 can include one or more structures in the interior 400 to facilitate placement and operation of the display module 402 and/or the cover glass 104. Here, a frame 408 can be positioned adjacent an edge of the display module 402. In some implementations, the frame 408 can extend around the entire perimeter of the display module 402 or a part thereof. Here, a frame 410 can be positioned adjacent an inside surface of the cover glass 104. For example, the frame 408 and/or 410 can be used for holding together the components of the display module 402.

The display device 100 can include a foam 412. In some implementations, the foam 412 can be positioned adjacent the outermost region 304 of the cover glass 104, and adjacent the frame 410. For example, an adhesive 414 can be positioned between the foam 412 and the frame 410. In some implementations, the foam 412 can prevent moisture or dirt from entering into the interior 400 of the housing 102. For example, the foam 412 can at least in part be positioned between the outermost region 304 and the edge 300 of the housing 102.

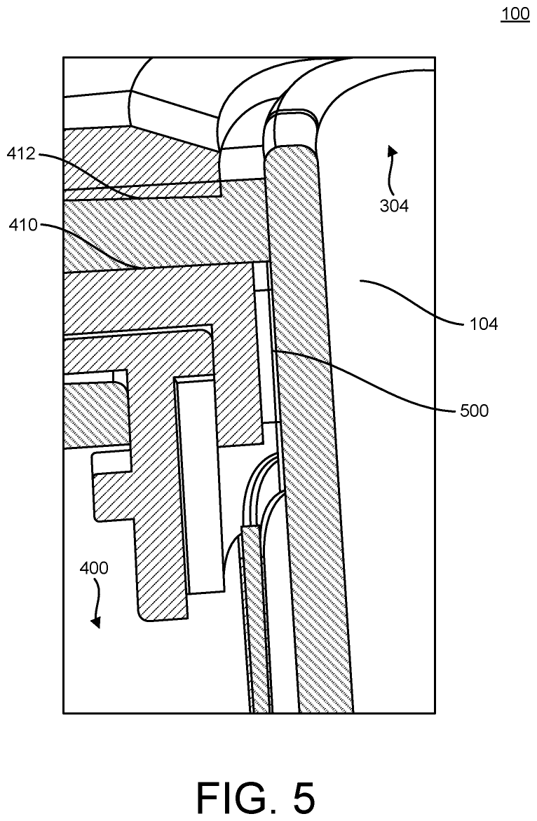

FIG. 5 shows another example of a cross section of the cover glass 104 and interior 400 of the display device of FIG. 1. At least part of the outermost region 304 of the cover glass 104 can be secured by way of a layer 500. The layer 500 can be attached or affixed to a structure in the interior 400. In some implementations, the layer 500 is applied to the frame 410. The layer 500 can include one or more types of adhesive. In some implementations, the layer 500 can include a double-sided tape. For example, such tape can include a backing of a sponge or foam material that has adhesive applied at both faces. In some implementations, the opposite side of the layer 500 from the interior 400 can abut a protective film of the cover glass 104, for example as described below.

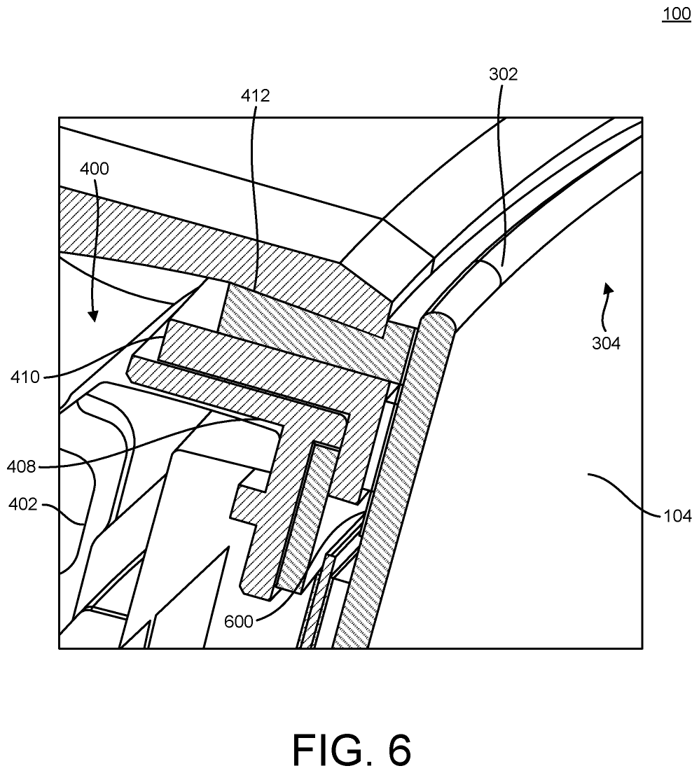

FIG. 6 shows another example of a cross section of the cover glass 104 and interior 400 of the display device 100 of FIG. 1. This example shows that the frame 408 is positioned against an edge of the display module 402, and that the frame 410 is positioned against the frame 408. For example, a clip or other fastener, and/or an adhesive, can be used for connecting the frame 408 and the display module 402 to each other. In some implementations, the frame 410 also has one or more connection (not shown) to the display module 402.

Here, a protective film 600 is applied to an inside of the cover glass 104. The protective film 600 can contain glass fragments from the cover glass 104. For example, this happens in case the cover glass should break or be fragmented in at least the outermost region 304. The protective film 600 can have a constant thickness. For example, the thickness can be selected based on the elongation properties of the film material, so that the protective film 600 provides a sufficient ability to contain glass fragments.

The protective film 600 can be transparent and can be applied (e.g., using an optically clear adhesive) to the inside surface of the cover glass 104 at the outermost region 304. In some implementations, the foam 412 can abut the protective film 600. The protective film 600 can extend around the entirety of the perimeter of the cover glass 104 or a part thereof. For example, the protective film 600 can extend throughout such part(s) of the perimeter of the cover glass 104 where the edge 302 is an exposed glass edge.

The above examples illustrate a vehicle display device (e.g., the display device 100) that includes: a housing (e.g., the housing 102) forming an opening (e.g., by the edge 300) to an interior (e.g., the interior 400). The vehicle display device includes a display module (e.g., the display module 402) positioned in the interior of the housing. The display module includes a substrate (e.g., the substrate 404 defining an active pixel area and/or touchscreen functionality). The vehicle display device includes a cover glass (e.g., the cover glass 104) that covers the opening to the interior of the housing. The cover glass is at least partially bounded by an exposed glass edge (e.g., the edge 302). The cover glass is attached to the substrate by an optically clear adhesive (e.g., the layer 500). An outermost region (e.g., the outermost region 304) of the cover glass extends beyond an edge of the substrate. The vehicle display device includes a protective film (e.g., the protective film 600) positioned along at least part of the exposed glass edge. The protective film is attached to an inside of the cover glass at the outermost region (e.g., as shown in FIG. 6).

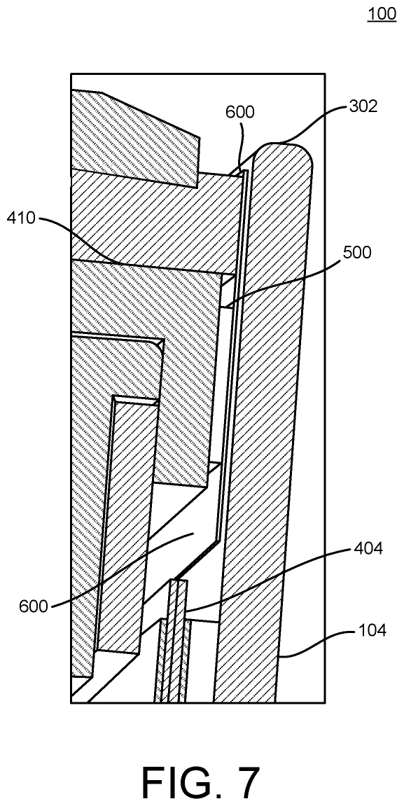

FIG. 7 shows another example of a cross section of the cover glass 104 and interior 400 of the display device 100 of FIG. 1. This illustration shows the layer 500 (e.g., an adhesive such as in a double-sided tape) positioned between the protective film 600 and the frame 410. In some implementations, the layer 500 is only applied where the protective film 600 covers the inside of the cover glass 104. For example, the layer 500 can be attached to a portion of the surface of the protective film 600.

The protective film 600 can extend substantially to the edge 302 of the cover glass 104. In some implementations, the top edge of the protective film 600 can be positioned within a tolerance distance of the edge 302. For example, this can involve positioning the top edge of the protective film 600 as close as possible to the edge 302 without accidentally causing the top edge to extend beyond the edge 302.

In the opposite direction, away from the edge 302 of the cover glass 104, the protective film can extend substantially as far in as possible without affecting the visual appearance of the display device 100. The protective film 600 can be positioned so that it does not interfere with assembly of other components, and entirely outside an active pixel area of the display device 100. In some implementations, the bottom edge of the protective film 600 can be positioned adjacent, or some distance away from, the layer 406 that attaches the central portion(s) of the cover glass 104 to the substrate 404. For example, the bottom edge of the protective film 600 can be positioned short of the edge of the substrate 404 so as to not interfere with the light visible by an occupant of the vehicle.

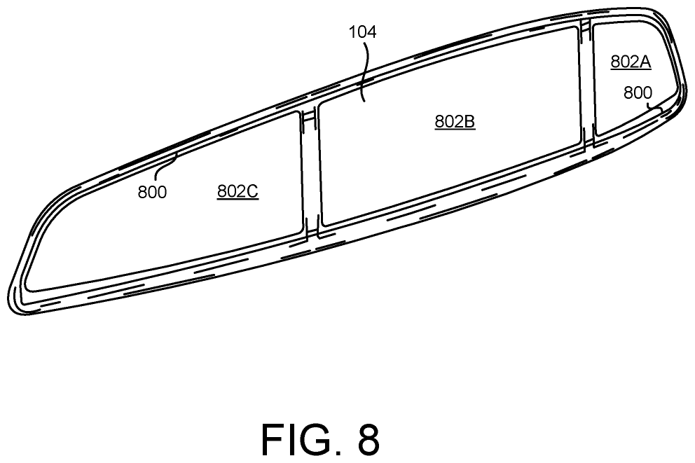

FIG. 8 shows a perspective view of an example of the cover glass 104 of FIG. 1 with a protective film 800. The protective film 800 can be used with one or more other examples described elsewhere herein. This example shows a rear of the cover glass 104 and the protective film 800 is attached to an inside surface thereof. The protective film 800 extends around an entire periphery of the cover glass 104. For example, the cover glass 104 can be configured to cover multiple display modules 802A-802C, as schematically illustrated against the cover glass 104. The protective film 800 can contain glass fragments from the cover glass 104.

The terms “substantially” and “about” used throughout this Specification are used to describe and account for small fluctuations, such as due to variations in processing. For example, they can refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%. Also, when used herein, an indefinite article such as “a” or “an” means “at least one.”

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein.

A number of implementations have been described. Nevertheless, it will be understood that various modifications may be made without departing from the spirit and scope of the specification.

In addition, the logic flows depicted in the figures do not require the particular order shown, or sequential order, to achieve desirable results. In addition, other processes may be provided, or processes may be eliminated, from the described flows, and other components may be added to, or removed from, the described systems. Accordingly, other implementations are within the scope of the following claims.

While certain features of the described implementations have been illustrated as described herein, many modifications, substitutions, changes and equivalents will now occur to those skilled in the art. It is, therefore, to be understood that appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A vehicle display device comprising:
a housing forming an opening to an interior;
a display module positioned in the interior of the housing, the display module including a substrate;
a cover glass that covers the opening to the interior of the housing, the cover glass at least partially bounded by an exposed glass edge, the cover glass attached to the substrate by an optically clear adhesive, wherein an outermost region of the cover glass extends beyond an edge of the substrate; and
a protective film positioned along at least part of the exposed glass edge, the protective film attached to an inside of the cover glass at the outermost region.

2. The vehicle display device of claim 1, wherein the protective film extends around an entirety of the exposed glass edge.

3. The vehicle display device of claim 1, wherein the exposed glass edge extends around an entire perimeter of the cover glass.

4. The vehicle display device of claim 1, wherein the protective film is transparent.

5. The vehicle display device of claim 1, wherein the protective film comprises a polymer resin.

6. The vehicle display device of claim 5, wherein the protective film comprises a polyethylene terephthalate film.

7. The vehicle display device of claim 1, wherein the substrate defines an active pixel area for the display module.

8. The vehicle display device of claim 7, wherein the protective film is positioned entirely outside the active pixel area.

9. The vehicle display device of claim 1, wherein the display module further includes a frame positioned adjacent at least one edge of the display module.

10. The vehicle display device of claim 9, further comprising an adhesive applied between the protective film and the frame.

11. The vehicle display device of claim 10, wherein the adhesive is included in a double-sided tape positioned between the protective film and the frame.

12. The vehicle display device of claim 10, wherein the adhesive attaches the protective film and the frame to each other and is not applied elsewhere at the inside of the cover glass.

13. The vehicle display device of claim 10, wherein the frame comprises a first frame and a second frame, wherein the adhesive is applied only between the protective film and the first frame, wherein the first frame is attached to the second frame, and wherein the second frame is attached to the display module.

14. The vehicle display device of claim 9, wherein the frame is positioned adjacent an entire perimeter of the display module.

15. The vehicle display device of claim 1, further comprising foam positioned between the outermost region and the edge of the housing.

16. The vehicle display device of claim 15, wherein the display module further includes a frame positioned adjacent at least one edge of the substrate, the vehicle display device further comprising adhesive positioned between the foam and the frame.

17. The vehicle display device of claim 15, wherein the foam abuts the protective film.

18. The vehicle display device of claim 1, wherein the vehicle display device comprises an instrument cluster device for a vehicle.

19. A vehicle display device comprising:
a housing forming an opening to an interior;
a display module positioned in the interior of the housing, the display module including a substrate;
a cover glass that covers the opening to the interior of the housing, the cover glass at least partially bounded by an exposed glass edge, the cover glass attached to the substrate by an optically clear adhesive, wherein an outermost region of the cover glass extends beyond an edge of the substrate; and
means for containing glass fragments of the cover glass, the means positioned along at least part of the exposed glass edge, the means attached to an inside of the cover glass at the outermost region.

20. The vehicle display device of claim 19, wherein the means extends around an entirety of the exposed glass edge, wherein the means is transparent, and wherein the means comprises a polyethylene terephthalate film.
